(19) United States
(12) Patent Application Publication
(10) Pub. No.: US 2020/0127364 A1
(43) Pub. Date: Apr. 23, 2020

(54) LAMINATE COMPRISING A WIRELESS COMMUNICATION CIRCUIT

(71) Applicant: THE DILLER CORPORATION, Cincinnati, OH (US)

(72) Inventor: Robert Jacob Kramer, Franklin, OH (US)

(73) Assignee: THE DILLER CORPORATION, Cincinnati, OH (US)

(21) Appl. No.: 16/658,001

(22) Filed: Oct. 18, 2019

Related U.S. Application Data
(60) Provisional application No. 62/747,663, filed on Oct. 18, 2018.

(51) Int. Cl. H01Q 1/22; H05K 1/03; G06K 7/10; G06F 16/955; H04W 4/02

(52) U.S. Cl. CPC H01Q 1/2216; H05K 1/0386; H04W 4/023; G06F 16/955; G06K 7/10386

(57) ABSTRACT

A laminate having a wireless communication circuit embedded within the laminate, comprising a first paper layer, a second paper layer disposed above the first paper layer, an insulating layer disposed above the second paper layer, an antenna provided as a set of windings on one of the first paper layer and the second paper layer, a wireless communication circuit, an electrically conducting connector segment disposed on the other of the first paper layer and the second paper layer, the electrically conducting connector segment being in electrical contact with the antenna to define a circuit, wherein the first paper layer and the insulating layer encapsulate the wireless communication circuit within the laminate.

### CROSS REFERENCE TO RELATED APPLICATION

This application claims the benefit under 35 U.S.C. § 119(e) of U.S. provisional patent application Ser. No. 62/747,663, filed Oct. 18, 2018, the entire disclosure of which is incorporated herein by reference, is hereby claimed.

### FIELD OF THE INVENTION

The disclosure generally relates to laminates comprising a wireless communication circuit. More particularly, the disclosure relates to a laminate with a wireless communication circuit embedded within the laminate.

### BACKGROUND OF THE INVENTION

Laminates are useful as surfacing materials, including as decorative surfaces, in many situations due to their combination of desirable qualities (e.g., superior wear, heat and stain resistance, cleanability, pleasing aesthetic effects, and cost). Laminate surfaces are composed of discrete layers, such as layers of resin-impregnated kraft paper that are pressed to form the laminate. One conventional decorative laminate is made by stacking three sheets of treated kraft paper (e.g., three sheets of phenol-formaldehyde resin-impregnated kraft paper), dry decorative paper (e.g., a print sheet), and a sheet of treated overlay paper (e.g. melamine-formaldehyde resin-impregnated tissue paper or acrylic resin-impregnated tissue paper), one on top of another and then bonding the stacked sheets together with heat and pressure. Typical applications have historically included furniture, kitchen countertops, table tops, store fixtures, bathroom vanity tops, cabinets, wall paneling, office partitions, and the like.

A high-pressure laminate process (HPL) is an irreversible thermal process wherein a “laminate stack” including resin-impregnated sheets of kraft paper undergoes a simultaneous pressing and heating process at relatively high levels of heat and pressure, such as temperatures greater than or equal to 125° C. and at least 5 mega Pascals (MPa) of pressure, typically for a press cycle of 30-50 minutes. Every press cycle includes both heating and cooling of the press platens. An HPL process contrasts with low pressure laminate processes (LPL) that are conducted at pressures of less than 5.0 MPa, typically between 2-3 MPa.

Generally speaking, a wireless communication circuit can be configured to uniquely identify items by using electromagnetic radiation to transmit identifying information.

One example of a wireless communication circuit is based on radio-frequency identifying (RFID) technology. An RFID system can include one or more “tags” that can be attached to various objects and a two-way radio transmitter-receiver or “reader” which uses an electromagnetic signal to automatically identify and track the tags. More specifically, the reader transmits a radio signal that is detected by the tag. The tag responds by transmitting a radio signal carrying encoded identifying information. The reader receives and decodes the transmission of the tag. RFID tags can be active or passive. Passive tags are able to utilize energy from a nearby RFID reader's interrogating radio signal. Active tags have a local power source (e.g., a battery) to power their transmissions, which enables many active tags to have much longer read distances than passive tags. Because the tags rely on radio signals, the tags can be embedded in the tracked object.

Typically, both passive and active RFID tags include an integrated circuit to implement the logic for storing and processing information, a non-volatile memory, and an antenna for receiving and transmitting the signals. Passive tags also include a means of collecting DC power from the incident reader signal. The tag information is stored in the non-volatile memory. The RFID tag includes either fixed or programmable logic for processing transmission data and detected data. RFID technology is used in many applications, for example, asset tracking in warehouses, airport baggage handling, employee identification badges can include RFID tags to allow for positive identification and monitoring of employees especially in secure areas, RFID tags can be embedded in luxury goods to combat counterfeiting, RFID tags can be attached to an item of manufacture such as a vehicle to track its progress through the assembly line, RFID-tagged pharmaceuticals can be tracked through warehouses, and implanted RFID microchips can be used for positive identification of animals such as livestock and lost pets.

Another example of a wireless communication circuit is based on near field communication (NFC) technology. NFC technology is generally related to RFID technology, but NFC technology allows for two-way peer-to-peer communication between NFC devices. Thus, NFC devices are often able to act both as readers and as transmitters. NFC is often used for short-range two-way radio communication. The communicating NFC devices must be in close proximity to each other, typically within only a couple centimeters (whereas RFID typically supports a range of 2 meters or more). Some NFC devices, however, are unidirectional such that they can only transmit information and thus operate as passive NFC devices only. Passive NFC devices do not require a power source, but require a means for collecting power from an incident active NFC device like passive RFID tags. NFC technology is used in many applications, for example, to facilitate contactless payment using a smartphone, to facilitate sharing of information, such as contact information and photographs, using a smartphone, to gain physical access by using NFC-enabled devices as keys or security badges.

Currently, many consumer- and work-environments include mounted networked computer tablet devices for a variety of purposes, for example, to allow individuals to view schedules, menus, and/or other information and to order and/or purchase products. Such mounted networked computer tablet devices limit the amount of usable counter or table space, which can be important especially in quick-service restaurant environments, museums, airports, office environments, and other locations where space is at a premium. Additionally, such mounted networked computer tablet devices can facilitate germ transmission because they are contacted by a number of individuals over time. In addition, at least for cost reasons, such mounted networked computer tablet also are limited to specific discrete locations, for example, at conventional point-of-sale locations.

### SUMMARY OF THE DISCLOSURE

This summary is provided to introduce a selection of concepts in a simplified form that are further described in the Detailed Descriptions. This summary is not intended to identify key features or essential features of the claimed subject matter, nor is it intended to be used to limit the scope of the claimed subject matter.

A laminate having a wireless communication circuit embedded within the laminate, comprising a first paper layer; a second paper layer disposed above the first paper layer; an insulating layer disposed above the second paper layer; an antenna provided as a set of windings on one of the first paper layer and the second paper layer; a wireless communication circuit; an electrically conducting connector segment disposed on the other of the first paper layer and the second paper layer, the electrically conducting connector segment being in electrical contact with the antenna and the wireless communication circuit to define a complete circuit; and wherein the first paper layer and the insulating layer encapsulate the wireless communication circuit within the laminate.

A laminate having a wireless communication circuit embedded within the laminate, comprising a first paper layer; a second paper layer disposed above the first paper layer; an insulating layer disposed above the second paper layer; an antenna comprising a particulate, electrically-conductive material and a binder, the antenna further optionally comprising microcrystalline cellulose, the antenna provided as a set of windings arranged on one of the first paper layer and the second paper layer; a wireless communication circuit in electrical contact with the antenna in a complete circuit; wherein the first paper layer and the insulating layer encapsulate the wireless communication circuit within the laminate.

A method for manufacturing a laminate having a wireless communication circuit embedded within the laminate, the method comprising: providing a first paper layer; providing a second paper layer above the first paper layer; forming an antenna as a set of windings on one of the first paper layer and the second paper layer; providing a wireless communication circuit; forming an electrically conducting connector segment on the other of the first paper layer and the second paper layer; providing an insulating layer above the second paper layer; and compressing and, heating during at least a portion of the compressing, a laminate stack comprising at least the first paper layer, the second paper layer, and the insulating layer according to a lamination process, thereby enhancing or establishing electrical contact between the electrically conducting connector segment, the wireless communication circuit and the antenna in a complete circuit, and encapsulating the wireless communication circuit within the laminate.

A method for manufacturing a laminate having a wireless communication circuit embedded within the laminate, the method comprising: providing a first paper layer; providing a second paper layer above the first paper layer; forming an antenna as a set of windings on one of the first paper layer and the second paper layer by depositing an electrically-conductive ink composition comprising a particulate, electrically-conductive material, a carrier liquid, and a polymer binder thereon; providing a wireless communication circuit on one of the first paper layer and the second paper layer; providing an insulating layer above the second paper layer; and compressing and, heating during at least a portion of the compressing, a laminate stack comprising at least the first paper layer, the second paper layer, and the insulating layer according to a lamination process, thereby enhancing or establishing electrical contact between the antenna and the wireless communication circuit in a complete circuit, and encapsulating the wireless communication circuit within the laminate.

### BRIEF DESCRIPTION OF THE DRAWINGS

FIG. 1 is a schematic diagram of an example of a laminate surfacing material having a wireless communication circuit embedded within the laminate that is integrated into a countertop;

FIG. 2 shows the first and second paper layers that comprise the wireless communication circuit in an exploded configuration;

FIG. 3 shows the first and second paper layers that comprise the wireless communication circuit in combination with a sensor and a power source in an exploded configuration;

FIG. 4A shows an exemplary power source suitable for use in a laminate, particularly a thin film battery in a laminate having a wireless communication circuit embedded within the laminate as described herein;

FIG. 4B shows the power source of FIG. 4A in an exploded configuration; and

FIG. 5. shows a system comprising a reader device and a laminate having a wireless communication circuit embedded within the laminate.

### DETAILED DESCRIPTION

A laminate having a wireless communication circuit embedded within the laminate is disclosed. In embodiments, the first paper layer and the insulating layer may encapsulate the wireless communication circuit within the laminate. The laminate may comprise one or more paper layers such as resin-impregnated paper layers and/or untreated paper layers. The laminate according to the instant disclosure includes an embedded wireless communication circuit and an antenna. The antenna is typically provided as a series of windings on one of the paper layers contained in the laminate. The antenna may have unexpected and surprising electrical conductivity, in particular, after the laminate has undergone a lamination process, preferably an HPL process. Advantageous inductive coupling of the antenna of the wireless circuit due to the unexpected and surprising electrical conductivity of the electrically-conductive material used to provide the antenna can lead to performance enhancements of the wireless communication circuit, particularly when provided in a passive RFID tag or a passive NFC device. As a result of this advantageous performance, signal transmission strength and distance suitable for passive wireless devices can advantageously be achieved. Additionally, such laminates having wireless communication circuits have greatly increased durability because the laminate effectively encapsulates the wireless communication circuit(s), for example, thereby making the wireless communication circuitry significantly more robust both structurally and operationally relative to conventional wireless communication circuits, substantially water-proof, and providing dust and sand resistance. Furthermore, because the resin-impregnated paper layers and the insulating layer provide a robust, durable water-proof enclosure for the wireless communication circuit(s), the laminates can be integrated into almost any surface (e.g., countertop including exterior countertop, walls including exterior walls, furniture including exterior furniture, for example a table, a desk, or an arm of a chair, doors including exterior doors, window frames including exterior window frames, an interior of a vehicle, etc.). An additional significant advantage of the laminates comprising a wireless communication circuit as disclosed herein is the ease with which these laminates can be manufactured, for example, without the need for lithographic techniques and without the need for a clean room.

In one embodiment, a laminate having a wireless communication circuit embedded within the laminate comprises a first paper layer; a second paper layer disposed above the first paper layer; an insulating layer disposed above the second paper layer; an antenna provided as a set of windings on one of the first paper layer and the second paper layer; a wireless communication circuit; an electrically conducting connector segment disposed on the other of the first paper layer and the second paper layer, the electrically conducting connector segment being in electrical contact with the wireless communication circuit and the antenna in a complete circuit. Advantageously, and despite being disposed on a separate, different paper layer from the paper layer including the antenna windings, the electrically conducting connector segment is capable of establishing electrical contact between the antenna and the electrically conducting connector segment, thereby allowing current flow from a first antenna terminus through both the wireless communication circuit and a second antenna terminus to complete or define an electrical circuit. The first paper layer and the insulating layer encapsulate the wireless communication circuit within the laminate.

In one specific implementation, the electrically conducting connection segment is in electrical contact with a first terminus of the antenna and a first pin or interconnect of the wireless communication circuit to complete the circuit and a second pin or interconnect of the wireless communication circuit is in electrical contact with a second terminus of the antenna. Alternatively, the wireless communication circuit can be disposed anywhere along the pathway of the tracks of the windings that form the antenna, or even along the electrically conducting connector segment, as long as the first and second terminuses of the antenna are electrically interconnected by the electrically conducting connector segment and/or the wireless communication circuit such that an electrical circuit is defined/completed as described herein.

The antenna may comprise a particulate, electrically-conductive material and a binder, the antenna further optionally comprising microcrystalline cellulose. In one aspect, the particulate, electrically-conductive material may comprise silver particles. Advantageously, the antenna can be capable of inductive coupling and serve as a surprisingly efficient means of collecting power for example, to provide power for a passive RFID tag, or a passive NFC device. As mentioned above, the antenna is provided as a set of windings. Typically, an electrically-conductive material as described herein is disposed on either the first or second paper layer in a suitable pattern to provide the antenna. Suitable patterns include, but are not limited to: continuous, meandering lines, spirals, circles, ovals, polyhedral shapes such as rectangles, squares, hexagons, octagons, spirangles, sawtooth waves, and combinations thereof.

The laminate having a wireless communication circuit embedded within the laminate generally further comprises first and second vias through the paper layer on which the antenna is provided. It should be understood that throughout this application via holes are alternatively referred to as vias once conductive material is included therein and a lamination process that establishes electrical contact between corresponding electrically conductive elements (typically, the antenna and the electrically conducting connector segment) is performed. Generally, vias provide the electrical connection between the antenna and the electrically conducting connector segment. Other known conductive structures can also be used for this purpose.

In one specific embodiment, one of the first via and the second via is in electrical contact with a terminus of the antenna and the other of the first via and the second via is in electrical contact with a pin or interconnect of the wireless communication circuit. The first and second vias are in electrical contact with first and second terminuses of the electrically conducting connector segment. The wireless communication circuit and the antenna windings both may be disposed on the same layer, for example, either the first paper layer or the second paper layer. Alternatively, the wireless communication circuit and the antenna may be disposed on different paper layers. In one such exemplary configuration, the wireless communication circuit may be disposed along the electrically conductive connector segment, for example, in the middle thereof with two interconnects or pins being in electrical contact with different portions of the electrically conducting connector segment.

The laminate having a wireless communication circuit embedded within the laminate may comprise first and second vias through the first paper layer and/or the second paper layer to electrically connect the electrically conducting connector segment to first and second terminuses of the antenna windings and thereby define or complete the electrical circuit. In a specific implementation, the first via is in electrical contact with a first terminus of the antenna and a first terminus of the electrically conducting connector segment and the second via is in electrical contact with a pin or interconnect of the wireless communication circuit and a second terminus of the electrically conducting connector segment.

As used herein, the terms “defined,” “complete,” and “completed” when used in combination with the term “circuit” refer to a complete circuit in which a current flows.

The wireless communication circuit may be configured to provide, to a reader device, a reference to an electronic resource to be retrieved by the reader device when the reader is within a certain distance of the wireless communication circuit. The reference may include a Universal Resource Locator (URL). The (referenced) electronic resource may be stored on a host operating on a local-area network (LAN) or a wide-area network (WAN).

In an exemplary implementation, the wireless communication circuit stores a reference to a resource disposed on a remote host. When the wireless communication circuit is within a certain radius of a reader device (as used herein, a reader device includes but is not limited to a smartphone, a tablet computer, a laptop computer, a smartwatch, a special-purpose device, etc.), the wireless communication circuit can provide the reference to the resource to the reader device, and the reader device can be configured to automatically retrieve the referenced resource from the remote host. The resource can be changed dynamically according to any desired schedule, whereas the reference can be “hard-coded” into the wireless communication circuit (the wireless communication circuit can store the reference permanently or semi-permanently, where provisioning the wireless communication circuit with a new reference requires specialized hardware and/or software). The reference for example can include a universal resource locator (URL) that identifies the location of a resource on a local-area network (LAN) or a wide-area network (WAN) such as the Internet.

As a more particular example, the wireless communication circuit can be used to provide a restaurant menu and provisioned with a URL to a resource on a certain Internet host, e.g., “http://www.host123.com/menu.html.” The management of the restaurant can update the online menu as often as desired, without the need to re-configure the instances of the wireless communication circuit embedded into restaurant counters, tables, for example. The wireless communication circuit can provide the URL in accordance with any suitable communication standard such as SO/IEC 14443 and ISO/IEC 18000-3, for example. A software application or the operating system running on the reader device can be configured to automatically interpret the information received from a wireless communication circuit as a URL and execute the HTTP GET command using the received information as a parameter, for example.

The wireless communication circuit includes control logic. The wireless communication circuit may further include or be coupled to a non-volatile memory. The memory may, for example, be configured to store data, such as personal data (e.g., credit card information to facilitate contactless payment, to allow for positive identification and/or monitoring of employees, etc.), specific identification of individual articles (e.g., for asset tracking, to combat counterfeiting, to track items of manufacture, etc.) and the like.

The wireless communication circuit may be a NFC device, a RFID tag, a Bluetooth® device (using short-wavelength UHF radio waves in the ISM band), a Wi-Fi device (technology for radio wireless local area networking of devices), or other suitable wireless communication circuit. The NFC device may be an active NFC device or a passive NFC device. The RFID tag similarly may an active RFID tag or a passive RFID tag. Because of the unexpectedly advantageous inductive coupling of the antenna of the wireless circuit due to the unexpected and surprising electrical conductivity of the electrically-conductive material used to provide the antenna, particularly after a high pressure lamination process, the wireless communication circuit is surprisingly efficient, particularly as a passive RFID tag or passive NFC device. The antenna can be capable of enhanced signal transmission strength, such that distances suitable for passive wireless devices can advantageously be achieved.

The wireless communication circuit may be coupled to a sensor capable of making a measurement or reading. Exemplary sensors include but are not limited to a GPS sensor, a temperature sensor, a pressure sensor, a humidity sensor, and a blood glucose sensor. At least a portion of the sensor may project beyond the laminate or be entirely encapsulated within the laminate. The sensor is configured to take a reading and communicate the reading to the non-volatile memory such that it can be stored. The wireless communication circuit may then transmit the reading to a reader device as described herein or modify one or more functions of the wireless communication circuit, for example, by disabling transmission based on certain sensor readings.

A system comprising a reader device and a laminate having a wireless communication circuit embedded within the laminate, the laminate including: a first paper layer, a second paper layer disposed above the first paper layer, an insulating layer disposed above the second paper layer, an antenna provided as a set of windings on one of the first paper layer and the second paper layer, a wireless communication circuit configured to transmit data to the reader device via the antenna, and an electrically conducting connector segment disposed on the other of the first paper layer and the second paper layer, the electrically conducting connector segment being in electrical contact with the antenna and the wireless communication circuit to define a complete circuit; and wherein the first paper layer and the insulating layer encapsulate the wireless communication circuit within the laminate is also disclosed. The wireless communication circuit is configured to transmit data via the antenna when the reader device is within a certain distance of the laminate. For example, the reader device can induce electric current in the wireless communication circuit when the reader device is within the certain distance of the laminate. The laminate may further include a battery configured to power the wireless communication circuit. The battery may be printed onto the first paper layer or the second paper layer. The laminate can further include a sensor coupled to the wireless communication circuit and the data transmitted to the reader device can include a reading from the sensor.

The insulating layer may be either a resin-impregnated decorative paper or a treated overlay. Alternatively, the laminate having a wireless communication circuit embedded within the laminate may further comprise a decorative paper layer, the decorative paper layer being disposed between the second paper layer and the insulating layer. Typically, one or more of the first paper layer and the second paper layer is impregnated with a resin material. The resin material may comprise a phenolic resin. The laminate having a wireless communication circuit embedded within the laminate typically further comprises (at least) a third paper layer disposed between the first paper layer and the insulating layer.

An article comprising the laminate having a wireless communication circuit embedded within the laminate as described herein can be disposed on any suitable supporting substrate, including but not limited to, particle board, wood, plastic, and metal substrates. The laminate can be adhered to such substrates as is well known and may also be disposed in a receptacle formed in such substrates.

A method for manufacturing a laminate having a wireless communication circuit embedded within the laminate according to the foregoing embodiment, comprises: providing a first paper layer; providing a second paper layer above the first paper layer; forming an antenna as a set of windings on one of the first paper layer and the second paper layer; providing a wireless communication circuit; forming an electrically conducting connector segment on the other of the first paper layer and the second paper layer; providing an insulating layer above the second paper layer; and compressing and, heating during at least a portion of the compressing, a laminate stack comprising at least the first paper layer, the second paper layer, and the insulating layer according to a lamination process, thereby enhancing or establishing electrical contact between the electrically conducting connector segment, the wireless communication circuit and the antenna in a complete circuit and encapsulating the wireless communication circuit within the laminate. As such, current flow from a first antenna terminus through both the wireless communication circuit and a second antenna terminus is enabled such that an electrical circuit is defined or completed. The method for manufacturing a laminate having a wireless communication circuit embedded within the laminate may further comprise forming first and second vias through the first paper layer and/or the second paper layer to enhance or promote electrically connecting the electrically conducting connector segment to the wireless communication circuit.

In another embodiment, a laminate having a wireless communication circuit embedded within the laminate comprises a first paper layer; a second paper layer disposed above the first paper layer; an insulating layer disposed above the second paper layer; an antenna comprising a particulate, electrically-conductive material and a binder, the antenna further optionally comprising microcrystalline cellulose, the antenna provided as a set of windings arranged on one of the first paper layer and the second paper layer; a wireless communication circuit in electrical contact with the antenna in a complete circuit; wherein the first paper layer and the insulating layer encapsulate the wireless communication circuit within the laminate.

The particulate, electrically-conductive material may comprise metal particles, for example silver particles. Advantageously, the antenna can be capable of inductive coupling and serve as a surprisingly efficient means of collecting power, for example, to provide power for a passive RFID tag, or a passive NFC device. The antenna can be capable of enhanced signal transmission strength, such that distances suitable for passive wireless devices can advantageously be achieved. As mentioned above, the antenna is provided as a set of windings. Typically, an electrically-conductive material as described herein is disposed on either the first or second paper layer in a suitable pattern to provide the antenna. Suitable patterns include, but are not limited to: continuous, meandering lines, spirals, circles, ovals, polyhedral shapes such as rectangles, squares, hexagons, octagons, spirangles, sawtooth waves, and combinations thereof.

The laminate having a wireless communication circuit embedded within the laminate may further comprise first and second vias through the paper layer on which the antenna is provided. Generally, vias can be provided to enhance the electrical connection between first and second terminuses of the antenna on one paper layer and the electrically conducting connector segment on a separate paper layer. Despite being disposed on a separate, different paper layer from the paper layer including the antenna windings, the electrically conducting connector segment is capable of establishing electrical contact between the antenna and the electrically conducting connector segment, thereby allowing current flow from the first antenna terminus through both the wireless communication circuit and the second antenna terminus and completing or defining an electrical circuit. In one specific implementation, the electrically conducting connection segment is in electrical contact with a first terminus of the antenna and a first pin or interconnect of the wireless communication circuit to define or complete the circuit. In this implementation, a second pin or interconnect of the wireless communication circuit is in electrical contact with a second terminus of the antenna. Alternatively, the wireless communication circuit can be disposed anywhere along the pathway of the tracks of the windings that form the antenna, or even along the electrically conducting connector segment, as long as the first and second terminuses of the antenna are electrically interconnected by the electrically conducting connector segment and/or the wireless communication circuit such that an electrical circuit is defined or completed as described herein.

In one specific embodiment, one of the first via and the second via is in electrical contact with a first terminus of the antenna and the other of the first via and the second via is in electrical contact with a pin or interconnect of the wireless communication circuit. The first and second vias are in electrical contact with first and second terminuses of the electrically conducting connector segment. The wireless communication circuit and the antenna windings both may be disposed on the same layer, for example, either the first paper layer or the second paper layer. Alternatively, the wireless communication circuit and the antenna may be disposed on different paper layers. In one configuration, the wireless communication circuit may be disposed along the electrically conductive connector segment, for example, in the middle thereof with two interconnects or pins being in electrical contact with different portions of the electrically conducting connector segments.

The laminate having a wireless communication circuit embedded within the laminate further may comprise first and second vias through the first paper layer and/or the second paper layer on which the antenna is disposed to electrically connect the electrically conducting connector segment to first and second terminuses of the antenna windings and thereby define or complete the circuit. In a specific implementation, the first via is in electrical contact with a first terminus of the antenna and a first terminus of the electrically conducting connector segment and the second via is in electrical contact with a pin or interconnect of the wireless communication circuit and a second terminus of the electrically conducting connector segment. Alternatively, the wireless communication circuit can be disposed anywhere along the pathway of the tracks of the windings that form the antenna, or even along the electrically conducting connector segment, as long as the first and second terminuses of the antenna are electrically interconnected by the electrically conducting connector segment and/or the wireless communication circuit such that an electrical circuit is defined/completed as described herein.

The wireless communication circuit may be configured to provide, to a reader device, a reference to an electronic resource to be retrieved by the reader device when the reader is within a certain distance of the wireless communication circuit. The reference may include a Universal Resource Locator (URL). The (referenced) electronic resource may be stored on a host operating on a local-area network (LAN) or a wide-area network (WAN).

In an exemplary implementation, the wireless communication circuit stores a reference to a resource disposed on a remote host. When the wireless communication circuit is within a certain radius of a reader device (as used herein, a reader device includes but is not limited to a smartphone, a tablet computer, a laptop computer, a smartwatch, a special-purpose device, etc.), the wireless communication circuit can provide the reference to the resource to the reader device, and the reader device can be configured to automatically retrieve the referenced resource from the remote host. The resource can be changed dynamically according to any desired schedule, whereas the reference can be “hard-coded” into the wireless communication circuit (the wireless communication circuit can store the reference permanently or semi-permanently, where provisioning the wireless communication circuit with a new reference requires specialized hardware and/or software). The reference for example can include a universal resource locator (URL) that identifies the location of a resource on a local-area network (LAN) or a wide-area network (WAN) such as the Internet.

As a more particular example, the wireless communication circuit can be used to provide a restaurant menu and provisioned with a URL to a resource on a certain Internet host, e.g., “http://www.host123.com/menu.html.” The management of the restaurant can update the online menu as often as desired, without the need to re-configure the instances of the wireless communication circuit embedded into restaurant counters, tables, for example. The wireless communication circuit can provide the URL in accordance with any suitable communication standard such as SO/IEC 14443 and ISO/IEC 18000-3, for example. A software application or the operating system running on the reader device can be configured to automatically interpret the information received from a wireless communication circuit as a URL and execute the HTTP GET command using the received information as a parameter, for example.

The wireless communication circuit includes control logic. The wireless communication circuit may further include or be coupled to a non-volatile memory. The memory may, for example, be configured to store data, such as personal data (e.g., credit card information to facilitate contactless payment, to allow for positive identification and/or monitoring of employees, etc.), specific identification of individual articles (e.g., for asset tracking, to combat counterfeiting, to track items of manufacture, etc.) and the like.

The wireless communication circuit may be a NFC device, a RFID tag, a Bluetooth® device (using short-wavelength UHF radio waves in the ISM band), Wi-Fi device (technology for radio wireless local area networking of devices), or other suitable wireless communication circuit. The NFC device may be an active NFC device or a passive NFC device. The RFID tag similarly may an active RFID tag or a passive RFID tag. Because of the unexpectedly advantageous inductive coupling of the antenna of the wireless circuit due to the unexpected and surprising electrical conductivity of the electrically-conductive material used to provide the antenna, particularly after a high pressure lamination process, the wireless communication circuit is surprisingly efficient, particularly as a passive RFID tag or passive NFC device.

The wireless communication circuit may be coupled to a sensor capable of making a measurement or reading. Exemplary sensors include but are not limited to a GPS sensor, a temperature sensor, a pressure sensor, a humidity sensor, and a blood glucose sensor. At least a portion of the sensor may project beyond the laminate or be entirely encapsulated within the laminate. The sensor is configured to take a reading and communicate the reading to the non-volatile memory such that it can be stored. The wireless communication circuit may then transmit the reading to a reader device as described herein or modify one or more functions of the wireless communication circuit, for example, by disabling transmission based on certain sensor readings.

A method for manufacturing a laminate having a wireless communication circuit embedded within the laminate according to the preceding embodiment, the method comprising: providing a first paper layer; providing a second paper layer above the first paper layer; forming an antenna as a set of windings on one of the first paper layer and the second paper layer by depositing an electrically-conductive ink composition comprising a particulate, electrically-conductive material, a carrier liquid, and a polymer binder thereon, the electrically-conductive ink composition optionally further comprising microcrystalline cellulose; providing a wireless communication circuit on one of the first paper layer and the second paper layer; providing an insulating layer above the second paper layer; and compressing and, heating during at least a portion of the compressing, a laminate stack comprising at least the first paper layer, the second paper layer, and the insulating layer according to a lamination process, thereby enhancing or establishing electrical contact between the antenna and the wireless communication circuit in a complete circuit, and encapsulating the wireless communication circuit within the laminate.

The insulating layer may be either a resin-impregnated decorative paper, untreated paper (e.g., tissue paper or any suitable paper not treated with melamine resin), treated overlay (e.g., paper treated with melamine resin), clear plastic film, glass, film provided on a decorative paper layer, or two or more of the aforementioned stacked together. In particular, when the insulating layer comprises a treated overlay paper layer, clear plastic film, or glass, the laminate may further comprise a dry or untreated decorative paper (also known as a print sheet) between the treated overlay paper layer clear plastic film, or glass, and the second paper layer. One or more of the first paper layer, the second paper layer, and any other paper layers that form the laminate stack may be impregnated with a resin material. The resin material may comprise a phenolic resin. The laminate having a wireless communication circuit embedded within the laminate typically further comprises (at least) a third paper layer disposed between the first paper layer and the insulating layer.

An article comprising the laminate having a wireless communication circuit embedded within the laminate as described herein can be disposed on any suitable supporting substrate, including but not limited to, particle board, wood, plastic, and metal substrates. The laminate can be adhered to such substrates as is well known and may also be disposed in a receptacle formed in such substrates.

The method for manufacturing a laminate having a wireless communication circuit embedded within the laminate may further comprise forming an electrically conducting connector segment on the other of the first paper layer and the second paper layer by depositing a second electrically-conductive ink composition comprising a particulate, electrically-conductive material, a carrier liquid, and a polymer binder thereon, the second electrically-conductive ink composition optionally further comprising microcrystalline cellulose. The method for manufacturing a laminate having a wireless communication circuit embedded within the laminate may further comprise forming first and second vias through the first paper layer and/or the second paper layer to enhance and/or establish electrical contact between the electrically conducting connector segment with both the wireless communication circuit and a terminus of the antenna by depositing a third electrically-conductive ink composition comprising a particulate, electrically-conductive material, a carrier liquid, and a polymer binder in first and second via holes, the third electrically-conductive ink composition optionally further comprising microcrystalline cellulose. The first, second, and third electrically-conductive ink compositions may be the same compositions or different compositions.

As described herein, the wireless communication circuit is “encapsulated” and thus provided with enhanced durability and protection against water damage by providing the wireless communication circuit between a first paper layer and an insulating layer such that the wireless communication circuit is at least partially protected or shielded from ambient atmosphere by the respective layers. Advantageously, it has been found that when laminates are exposed to the heat and pressure in a lamination process, preferably a high pressure lamination process, the antenna has surprisingly higher conductivity than through other conventional manufacturing techniques. The high pressure lamination process allows for accurate control of temperature and pressure (e.g., heating and cooling cycles) in order to control the rate of dimensional change of layers and surprisingly leads to enhanced electrical conductivity of the components formed using the electrically-conductive material.

In each of the foregoing embodiments, an exemplary, representative laminate comprises a stack comprises a first untreated kraft paper layer, a first glue film layer above the first untreated kraft paper, a second untreated kraft paper layer, a second glue film layer above the second untreated kraft paper, and an insulating layer such that the insulating layer is disposed above the second glue film layer. The antenna is provided as a set of windings and can be arranged on either the first paper layer or the second paper layer.

Typically, the stack includes an additional glue film layer disposed below the first untreated kraft paper layer so as to allow a sufficient amount of resin to saturate the laminate during a lamination process, in order to provide sufficient mechanical strength to the final formed laminate. The layers of the laminate are typically stacked to provide a laminate stack and the wireless communication circuit is encapsulated between the first paper layer and the insulating layer by subjecting the laminate to a lamination process, typically, a high pressure lamination process, which surprisingly results in advantageously enhanced densification and excellent conductivity of the windings/tracks that make up the antenna. It should be noted that the same electrically-conductive material may be used to provide the antenna and the vias, but different electrically-conductive materials may also be used.

In one preferred embodiment, a method of making a laminated surface material comprises providing a laminate stack comprising a first untreated kraft paper layer, a first glue film layer (above the first untreated kraft paper), a second untreated kraft paper layer (above the first untreated kraft paper), and an insulating layer (above the first untreated kraft paper), such that the insulating layer is disposed above the first untreated kraft paper; providing an antenna comprising a set of windings, for example, by depositing a first electrically conductive material layer in a suitable pattern over the first untreated kraft paper layer; and compressing the stack according to a lamination process. Typically, the stack includes an additional glue film layer disposed below the first untreated kraft paper layer so as to allow a desirable amount of resin to saturate the laminate during the lamination process and provide sufficient mechanical strength to the final formed laminate. By providing the antenna on untreated kraft paper, significantly improved alignment of via holes formed in the stack can be achieved than when the antenna is disposed on resin-impregnated paper layers. A glue film layer as used herein is a layer having a sufficient amount of thermoset resin to saturate an adjacent untreated paper layer (e.g., a decorative layer or an untreated kraft paper layer). Typically, a glue film layer will comprise a paper layer having between 30-80 percent by weight of a thermoset resin. Preferably, the thermoset resin of the glue film comprises phenol-formaldehyde resin.

Antennas can be formed by depositing (e.g., inkjet printing, flexographic printing, gravure printing, screen printing, extrusion printing, and the like) a first electrically-conductive material in a winding pattern over the first paper layer or the second paper layer. To provide the antenna, the electrically-conductive material described above may be disposed in a pattern over the first paper layer and other paper layers in various embodiments of the present disclosure. Suitable patterns include, but are not limited to: continuous, meandering lines, spirals, circles, ovals, polyhedral shapes such as rectangles, squares, hexagons, octagons, spirangles, sawtooth waves, and combinations thereof. Two-dimensional multiple angle spirangles including but not limited to 3-angle, 4-angle, 7-angle, and 70-angle spirangle patterns are particularly useful. Preferably, the antenna is provided by disposing the electrically conductive material in patterns which provide a relatively large amount of electrically-conductive material on the paper layer while maintaining a gap between adjacent portions of the electrically-conductive pathway. The cross-sectional area of any linear portion of the antenna may be important in circumstances where electrical resistance is to be minimized as the total electrical resistance of any electrically-conductive track is the product of the specific resistance per square (related to cross-sectional area) and the track length. In other words, as understood by those skilled in the art, greater cross-sectional areas lead to lower overall track resistances which lead to lower resistive heating for similar electric current levels.

It may be preferable to optimize the relationship between track vertical thickness, the cross sectional area and the pitch (i.e., the distance between two adjacent linear portions or tracks of the electrically-conductive material disposed on a paper layer) which should be controlled to be as small as possible while ensuring that the two adjacent linear portions do not touch. It is also important to note that the pressure involved in the compression steps of the high pressure lamination process reduces the vertical thickness of the electrically-conductive track. The overall effect on total electrical resistance may vary as the compression may increase specific resistance of the electrically-conductive material by decreasing the cross-sectional area, while also increasing electrically-conductive contact between electrically-conductive particles within the electrically-conductive materials, thus decreasing resistance. Thus, various factors affect overall resistance. Preferably one or more such factors are considered in efforts to reduce overall resistance, and thus, heat generation.

The methods for manufacturing a laminate having a wireless communication circuit embedded within the laminate typically include forming at least first and second via holes through a paper layer in order to electrically interconnect the windings of the antenna and the electrically-conductive connector segment disposed on another paper layer. In some implementations, the first and second paper layers are separated by additional intervening layers, with the vias traversing through any intervening layers as well. The via holes described may be formed, cut through, or punched through, such as by a mechanical device or a laser, such that upon stacking paper layers on top of each other, the vias traverse each other. One via may be provided at a terminus of the windings of the antenna and another via may be provided at an interconnect or pin of the wireless communication circuit, with another interconnect or pin of the wireless communication circuit being in electrical contact with a second terminus of the windings of the antenna. Provided that the vias are at least partially filled with an electrically conductive material, it is possible to establish an electrical connection between the antenna provided as a set of windings on one of the first paper layer and the second paper layer and the electrically conducting connector segment disposed on the other of the first paper layer and the second paper layer, especially after a lamination process is conducted. Filling the first and second vias with electrically-conductive material can be accomplished using various deposition techniques including but not limited to inkjet printing, gravure printing, and screen printing. Suitable methods for forming vias between two paper layers, whether directly adjacent or separated by additional layers, are described in U.S. patent application Ser. No. 15/908,795 (corresponding to US Patent Publication No. US20190267562A1), which is hereby incorporated herein by reference in its entirety.

Electrically-conductive materials suitable for use in accordance with the various embodiments of the present disclosure include any material which can be disposed upon the first paper layer and other paper layers that may be included as part of the laminate, such as resin-impregnated paper, and which may be electrically electrically-conductive. Suitable electrically-conductive materials include metals, alloys, and electrically-conductive inks. In some embodiments, the composition of the electrically-conductive material includes: (i) a particulate, electrically-conductive material; (ii) a binder; and optionally (iii) a microcrystalline cellulose component. Electrically-conductive inks are commercially available from a number of sources and can be prepared using a number of known methods. Suitable electrically-conductive inks are described in U.S. patent application Ser. No. 15/951,709 (corresponding to U.S. Patent Publication No. US20180298220A1), which is hereby incorporated herein by reference in its entirety.

The particulate, electrically-conductive material may include any one of metals, alloys, electrically-conductive carbons (e.g., electrically-conductive allotropes of carbon, graphites), electrically-conductive polymers (e.g., polypyrrole), electrically-conductive metallized polymers (e.g., metallized polyethylene terephthalates), and combinations thereof. In a preferred aspect, the particulate electrically-conductive material comprises silver and/or silver alloys. Electrically-conductive ink compositions which may be disposed to provide electrically-conductive material on a paper layer and are thus suitable for use in various embodiments of the present disclosure typically include particles comprising metal, metal alloys, electrically-conductive carbon, or other electrically-conductive materials such as polymers, in a carrier medium which may include other polymers, solvents and additives. Particularly preferred electrically-conductive inks suitable for use in various preferred embodiments of the present disclosure include silver and/or electrically-conductive carbon particles. Various known methodologies such as inkjet printing, screen printing, flexographic printing, gravure printing, or extrusion printing may be used to dispose the electrically-conductive ink compositions on the paper layers.

One embodiment of an electrically-conductive ink composition suitable for providing the particulate electrically-conductive material is an electrically-conductive ink composition comprising: (i) a particulate, electrically-conductive material; (ii) a carrier liquid; (iii) a polymer binder; and (iv) a microcrystalline cellulose component. Another embodiment of an electrically-conductive ink composition suitable for providing the particulate electrically-conductive material is an electrically-conductive ink composition comprising: (i) a particulate, electrically-conductive material; (ii) a carrier liquid; (iii) a polymer binder; and (iv) a microcrystalline cellulose component; wherein the particulate, electrically-conductive material comprises a component selected from the group consisting of silver and silver alloys; and wherein the microcrystalline cellulose component is present in an amount of from about 0.05% to about 10% by weight based on the composition and has an average particle size of from about 20 to about 100 μm. Throughout this disclosure, references to electrically-conductive material or ink composition should be understood to include the electrically-conductive material or ink composition itself in addition to electrically-conductive particles left behind after the electrically-conductive material or ink has dried. In certain embodiments of the present disclosure, the microcrystalline cellulose component may include two or more microcrystalline celluloses having different average particle sizes. As noted above, disposing methods such as inkjet printing, flexographic printing, gravure printing, screen printing, and extrusion printing may dispose the electrically-conductive material onto the paper layers, such as kraft paper and overlay paper, but depending on the type of paper, the electrically-conductive material may or may not penetrate completely through the paper.

If kraft paper (i.e., unbleached paper that is between 50-400 GSM (or g/m²)) is used, and an electrically-conductive ink composition is disposed thereon, the electrically-conductive material may penetrate through at least a portion, for example about halfway through the kraft paper, whereas if overlay paper (i.e., bleached paper that is between 10-50 GSM) having less than half the basis weight of kraft paper is used, and an electrically-conductive ink composition is disposed thereon, the electrically-conductive material will typically penetrate completely through the overlay paper. As such, in order to couple electrically-conductive material provided on different consecutive layers of kraft paper together, via holes can be cut at least halfway through the kraft paper, so that electrically-conductive material disposed over a top surface of the kraft paper penetrates halfway through the first kraft paper to form a via and establish an electrical connection with a same type or different type electrically-conductive material provided on a top surface of a second kraft paper layer underlying the first kraft paper layer. Because disposed electrically-conductive material may penetrate completely through overlay paper, it is not necessary to cut visa holes in the overlay paper to form a via and couple the electrically-conductive material disposed on a top surface of a first overlay paper layer to a same type or different type electrically-conductive material disposed on a top surface of a second paper layer disposed thereunder. Once disposed, the electrically-conductive material may be subject to a lamination process such as the high pressure lamination process involving pressing at elevated temperature and pressure.

The laminate in accordance with the various embodiments of the present disclosure may include one or more electrical contact pads which allow an electrical connection to be established to the antenna from the exterior of the laminate. Thus, an external power source can be provided to power the wireless communication circuit, for example, if an active RFID tag or an active NFC device is desired. The laminate may further be coupled to a component or components connected to the electrical contact pads on the exterior of the laminate which component(s) are configured to accept AC, or pulsed DC, voltage input from an electrical source such that the electrically-conductive material(s) are provided with a current. Such components may include, but are not limited to various receptacles for AC and DC plugs, and terminal boxes or the like for hard-wiring AC or DC inputs. Electrical contact with the laminates may also be established by coupling any electrically-conductive material to the electrical contact pads using various structures including but not limited to metal tabs, screws, prongs, cylindrical receptacles, spring-loaded pins, etc. Additionally, methods of establishing permanent electrical contact can be established by affixing an external component or conductor to the electrical contact pads by soldering or the use of conductive adhesives.

In each of the foregoing embodiments, the laminates having a wireless communication circuit embedded within the laminate may further comprise a photovoltaic cell embedded within the laminate and coupled to the wireless communication circuit. The photovoltaic device may effectively serve as an external power source to power the transmission of the wireless communication circuit. Photovoltaic cells embedded within laminates are described in U.S. patent application Ser. No. 15/908,795 (corresponding to U.S. Patent Publication No. US20190267562A1), which is hereby incorporated herein by reference in its entirety.

In each of the foregoing embodiments, the laminate having a wireless communication circuit embedded within the laminate may further may further comprise a battery embedded within the laminate and coupled to the wireless communication circuit. The battery may be provided on one of the first paper layer and the second paper layer. The battery may alternatively be provided on an alternative substrate, for example, a substrate comprising fiber glass or polyimide film that is then incorporated into the laminate. The battery preferably comprises a thin film battery. The thin film battery generally comprises an anode, a cathode, and an electrolyte between the anode and the cathode. The thin film battery may further comprise an anode current collector in contact with the anode and a cathode current collector in contact with the cathode. The electrolyte may comprise a solid polymer electrolyte, a gelled polymer electrolyte, or a solid-state ionic electrolyte. The electrolyte may be provided in a further paper layer disposed between the anode and the cathode, the further paper layer being impregnated with the electrolyte.

Such batteries can be screen printed layer by layer, or can be assembled by arranging small thin components together. Printing the battery is preferable and may be accomplished via screen printing, offset printing, gravure printing, or inkjet printing. A thin film battery may alternatively be produced by sputtering one or more of the various layers onto polyimide film or another suitable substrate.

The cathode may comprise a lithium containing material. Thin film batteries often employ cathodes comprising lithium-oxide complexes such as LiCoO₂, LiMn₂O₄ and LiFePO₄. Suitable printable LiFePO₄ formulations are described in U.S. Patent Publication No. US20150325856A1, which is hereby incorporated herein by reference in its entirety.

The anode may comprise a graphite-based material, plated lithium, a lithiated Li-ion material. The anode may be provided by depositing or printing a very low polymer (non-graphite polymer) content graphite based conductive ink.

The electrolyte preferably comprises a solid polymer electrolyte such as those based on PEO (polyethylene oxide), also known as PEG (polyethylene glycol). A suitable example is NANOMYTE® H-polymer (NEI Corporation). Both organic and inorganic solid polymer electrolytes may be used. Lithium lanthanum titanates (LLTO), garnet-type zirconates (LLZO), Li2S—P2S5-based glasses, and lithium phosphate oxynitride (LiPON) have been used commercially in solid lithium ion batteries. A gel type electrolyte may also be used.

An additional paper layer that is impregnated with a solid polymer electrolyte may be provided between the anode and the cathode to function as a “separator”. Additionally, if full saturation of this paper layer is avoided, liquid electrolyte may be added into the system.

The cathode current collector may comprise Co/Au, Pt, or the electrically-conductive inks including silver and/or electrically-conductive carbon particles as described herein.

The anode current collector may comprise Cu or the electrically-conductive inks including silver and/or electrically-conductive carbon particles as described herein.

As a non-limiting example, the cathode may comprise LiCoO₂, the electrolyte may comprise lithium phosphate oxynitride (LiPON), the anode may comprise graphite, and the anode/cathode current collectors may comprise aluminum, silver, copper, or gold.

As mentioned previously, a laminate's paper layers may be impregnated with resin such that the paper layers, when stacked and compressed in the lamination process, can be cured or cross-linked. The resin can be a thermoset resin such that the paper layers in a stacked relationship can be compressed and heated to cure the thermoset resin. Specific suitable resins for use in the various embodiments of the present disclosure may differ depending on whether the resin-impregnated paper layer is an outer protective layer (e.g., an insulating layer), or an interior core layer (e.g., a treated kraft paper layer), or a base layer of the laminate surfacing material (e.g., a treated kraft paper layer). Generally, resin-impregnated paper layers are impregnated with any suitable thermoset resin including, but not limited to, acrylics, polyesters, polyurethanes, phenolics, phenol-formaldehydes, urea-formaldehydes, aminoplastics, melamines, melamine formaldehydes, diallyl-phthalates, epoxides, polyimides, cyanates, and polycyanurates, or copolymers, terpolymers or combinations thereof. Phenol-formaldehydes are generally preferred for impregnating kraft paper and acrylics or melamine-formaldehydes are generally preferred for impregnating overlay paper. As used in this disclosure, an insulating layer may be a translucent layer. A translucent layer means any layer that permits at least some light to pass there through. In other words, layers that are partially opaque are included as translucent layers.

In some implementations, resin-impregnated paper layers which are core layers are impregnated with a phenolic and/or epoxy resin, such as, for example, a phenolic-formaldehyde resin. Impregnating paper layers with a resin can be carried out in any suitable manner sufficient to apply a controlled quantity of resin to the paper, including but not limited to, screen printing, rotary screen printing, dip and squeeze, dip and scrape, reverse roll-coating, Meyer bar, curtain coating, slot-dye and gravure roller. The weight percentage of resin applied, relative to the weight of the paper layer as measured on an oven dried basis, may be in the range of about 5 to 75%, with a preferred resin content percent (determined relative to final weight) of about 15-45%. As the resins used in the impregnating step are normally aqueous or solvent based solutions, it is common in the laminating process to include a paper drying stage to reduce the paper solvent loading. In the various embodiments of the present disclosure, the weight percent level of residual solvent in the impregnated paper may be 2.5-15% with a typical level of about 5%. As used herein, cured can refer to both curing of a thermoset resin in the sense of its irreversible setting, or the crosslinking of other polymers with a separate cross-linker or by various forms of energy, or any means of fixing the resin when the laminate surfacing material is in its compressed form such that the wireless communication circuit, the antenna, and the electrically conducting connector segment (when present) are encapsulated and will remain so during normal operation.

Suitable papers which may be used, particularly in resin-impregnated paper layers, in accordance with the various embodiments of the present disclosure include but are not limited to: cellulose fiber, synthetic woven or non-woven fiber, or/and microfiber or/and nanofiber, mixtures of cellulose or/and synthetic fiber based papers or/and mineral fiber based papers or/and glass fiber based papers, coated or non-coated, pre-impregnated or non pre-impregnated that could be generally used for the production of laminates. In various embodiments of the present disclosure, paper suitable for use in resin-impregnated paper layers has at least one of the following properties: a minimum wet strength in the machine direction of 1400 cN/30 mm in accordance with the test method of the International Standard DIN ISO 3781, a Klemm absorbency range (capillary rise) in the machine direction of 30 to 90 mm/10 min in accordance with the test method of the International Standard DIN ISO 8787 with a preferred absorbency of 45 mm/10 min, Ash content 0 to 50% depending of the intrinsic nature of the paper used in accordance with the test method of the International Standard Din ISO 2144, a basis weight range of 10 to 400 GSM at moisture content range of 2 to 8% in accordance with the test method of the International Standard DIN ISO 536, a pH (on hot extract) between about 4 to 9 in accordance with the test method of the International Standard DIN ISO 6588. In various embodiments of the present invention, papers comprising at least a portion of recycled materials may be used.

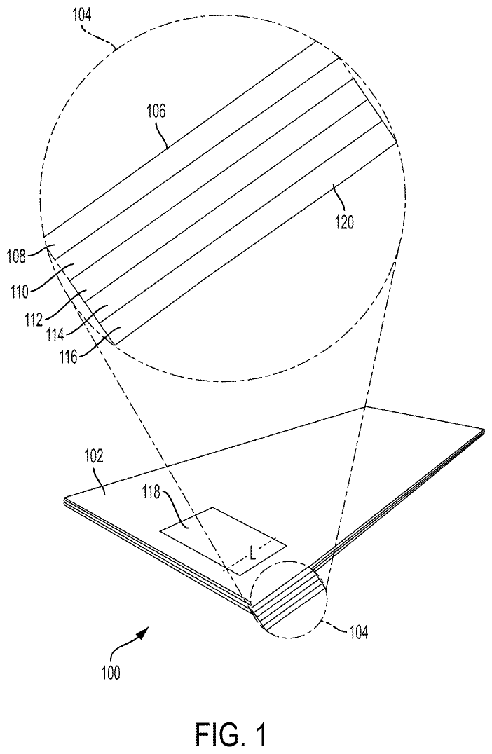

FIG. 1 is a schematic diagram of an example of electrically functional system 100 including a laminate surfacing material 106 with an embedded wireless communication circuit integrated into a countertop 102. Other types of surfaces may also be covered with the laminate surfacing material 106 (e.g., walls including exterior walls, furniture including exterior furniture, for example a table, a desk, or an arm of a chair, doors including exterior doors, window frames including exterior window frames, an interior of a vehicle, etc.). The laminate surfacing material 106 includes an antenna provided as a set of windings (not shown) on one of the paper layers included therein, a wireless communication circuit (not shown), and an electrically conducting connector segment (not shown) disposed on a second paper layer included therein, the electrically conducting connector segment being in electrical contact with the antenna.

Bubble 104 further illustrates a cross-section view of an example laminate according to the disclosure. Several layers forming the laminate surfacing material that encapsulate the wireless communication circuit are generally illustrated in bubble 104. In the cross-section view of bubble 104, first paper layer 112, second paper layer 114, optional paper layer 116, optional decorative paper layer 110, and insulating layer 108 are visible. In practice, electrically-conductive material may be disposed on one or more of layers 112-116 constituting the laminate surfacing material 106 to provide the antenna and the electrically conducting connector segment. The electrically functional system 100 can be used for a variety of purposes for example, to facilitate contactless payment using a suitable reader device, to facilitate sharing of information, such as menu information, museum tour information, and scheduling information to allow reservations of office spaces or restaurant seating, using a suitable reader device, and to gain physical access by using suitable reader device as a key or security badge. Generally, a reader device can be placed in proximity to area 118 in order to actuate the antenna of the wireless communication circuit and receive any information therefrom.

The surface 102 may be equipped with an electronic device, such as a power supply to provide AC, or pulsed DC, voltage such that the electrically-conductive material and the integrated electronic component are provided with a current. The electronic device may be electrically connected to a via coupled to the antenna and/or electrically conducting connector segment disposed in layers 112-116 to provide the necessary voltage to drive the antenna.

Although the laminate 100 as illustrated includes paper layer 112 and optional paper layers 114, 116, optional decorative paper layer 110, and an insulating layer 108, it should be understood that the present disclosure is not limited to the precise configuration shown. For instance, additional paper layers may be stacked below insulating layer 108. Such additional paper layers may provide space for disposing additional electrical components such as the photovoltaic device within the laminate structure.

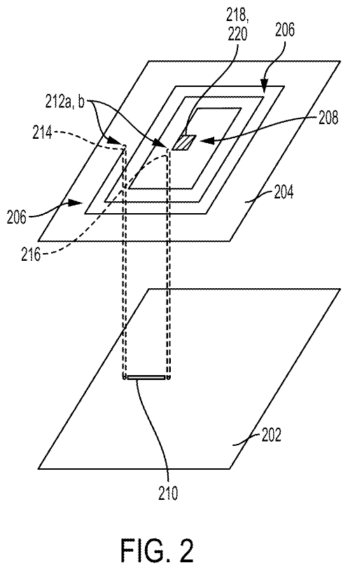

FIG. 2 shows exemplary first and second paper layers for use in a laminate 200. Specifically, first paper layer 202 and second paper layer 204 are illustrated. An antenna 206 is provided as a set of windings the second paper layer. A wireless communication circuit 208 is also provided on the second paper layer 204 of the wireless communication circuit 208 to define or complete the circuit and a second pin or interconnect 218 of the wireless communication circuit 208 is in electrical contact with a second terminus of the antenna 220. It should be understood that the present disclosure is not limited to the precise configuration of the two paper layers 202, 204 shown. For instance, additional paper layers may be provided between the first and second paper layers 202, 204. Additionally, while FIG. 2 shows the wireless communication circuit 208 and the antenna 206 disposed on the same paper layer, specifically, the second paper layer 204, the wireless communication circuit 208 and the antenna 206 may be disposed on different paper layers. For example, the wireless communication circuit 208 may be disposed on the same paper layer as the electrically conductive connector segment 210, for example, in the middle thereof with two interconnects or pins of the wireless communication circuit being in electrical contact with different portions of the electrically conducting connector segment 210. Still further, the relative positioning of the antenna 206 on the second paper layer 204 and the electrically conducting connector segment 210 on the first paper layer 202 may be changed. Still further, vias 212a, 212b may not be needed, particularly if an appropriate second paper layer 204 is selected. Moreover, the specific locations of the vias 212a, 212b can be changed as long as the first and second terminuses of the antenna are electrically interconnected by the electrically conducting connector segment and/or the wireless communication circuit such that an electrical circuit is completed or defined.

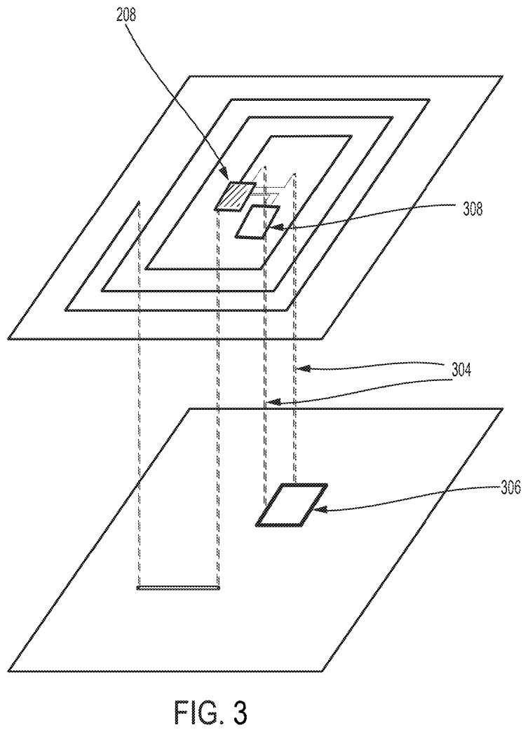

The configuration of FIG. 3 is generally similar to the configuration of FIG. 2, except that the wireless communication circuit 208 in FIG. 3 is also coupled to a sensor 308 and, through vias 304, a power source 306. In this implementation, the power source 306 and the wireless communication circuit 208 are disposed on different paper layers. More generally, however, the components 208, 308, and 306 can be distributed among two or more paper layers in any suitable manner.

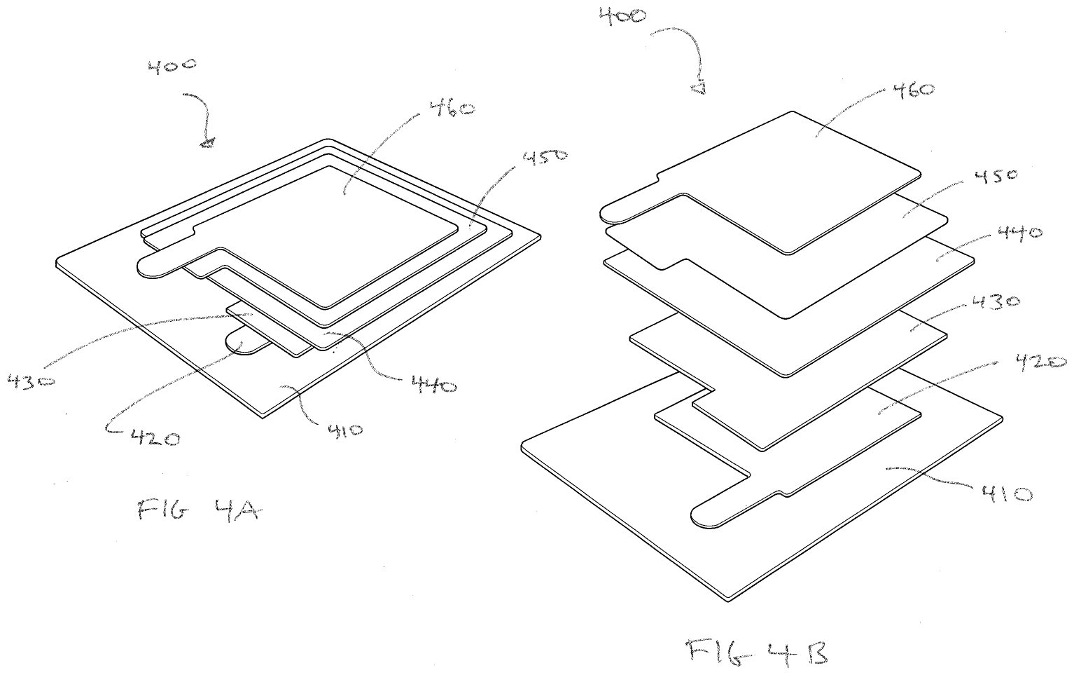

FIG. 4A illustrates an exemplary power source 400, particularly a thin film battery, suitable for use in a laminate having a wireless communication circuit embedded within the laminate as described herein in greater detail. Thin film battery 400 includes a substrate 410, which may be provided by the first or second paper layer of the laminate, or separately provided as described above. A cathode current collector 420 is disposed above the substrate 410. A cathode 430 is disposed above the cathode current collector 420. An electrolyte 440, which can be provided as an electrolyte-impregnated paper layer as described above, is disposed above the cathode 430. An anode 450 is disposed above the electrolyte 440. An anode current collector 460 is disposed above the anode 450. FIG. 4B shows the various components of the thin film battery 400 in an exploded configuration.

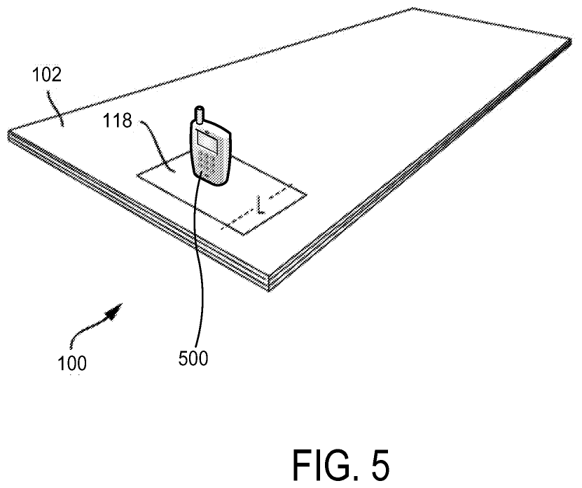

Now referring to FIG. 5, the electrically functional system 100 discussed above can provide data to a reader device 500. As discussed above, the data can include a reference (such as a URL or another suitable type of a link) to a resource stored on a server accessible to the reader device 500 or, in another implementation, a description of a product, service, etc. In some implementations and/or scenarios, the electrically functional system 100 also can receive power from the reader device 500. In general, the reader device 500 can include any suitable computing device capable of wireless communications. The reader device 500 can be a tablet computer, a smartphone, a laptop computer, a wearable device such as a smartwatch, a special-purpose computing device configured to track athletic activity, etc. The reader device 500 can include processing hardware such as a processor, a wireless communication circuit, and an antenna. In some implementations, the reader device 500 periodically actuates its antenna and transmits sufficiently powerful signals to induce electric current in the wireless communication circuit of the laminate in the electrically functional system 100 so as to power the communication circuit.

More particularly, the signal transmitted by the reader device 500 can power the electrically functional system 100 when the reader device 500 is within a certain threshold distance of the laminate. The threshold distance (e.g., 2 cm, 5 cm, 10 cm, 1 m) depends at least in part on the strength of the signal transmitted by the reader device 500 and the size and geometry of the antenna of the electrically functional system 100.

As used herein, the singular terms “a” and “the” are synonymous and used interchangeably with “one or more” and “at least one,” unless the language and/or context clearly indicates otherwise. Accordingly, for example, reference to “a paper layer” or “the paper layer” herein or in the appended claims can refer to a single paper layer or more than one paper layer. Additionally, all numerical values, unless otherwise specifically noted, are understood to be modified by the word “about.”

For simplicity and clarity of illustration, elements in the figures are not necessarily to scale, and the same reference numbers in different figures denote the same elements. For clarity of the drawing, layers and electrically-conductive materials may be shown as having generally straight line edges and precise angular corners. However, those skilled in the art understand that the edges need not be straight lines and the corners need not be precise angles.

Certain terminology is used in the following description for convenience only and is not limiting. Ordinal designations used herein and an it appended claims, such as “first”, “second”, “third”, etc., are solely for the purpose of distinguishing separate, multiple, similar elements (e.g., a first paper layer and a second paper layer), and do not import any specific ordering or spatial limitations unless otherwise required by context.

The applications and benefits of the systems, methods and techniques described herein are not limited to only the above examples. Many other applications and benefits are possible by using the systems, methods and techniques described herein.

Moreover, although the foregoing text sets forth a detailed description of numerous different embodiments, it should be understood that the scope of the patent is defined by the words of the claims set forth at the end of this patent. The detailed description is to be construed as exemplary only and does not describe every possible embodiment because describing every possible embodiment would be impractical, if not impossible. Numerous alternative embodiments could be implemented, using either current technology or technology developed after the filing date of this patent, which would still fall within the scope of the claims.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

What is claimed:

1. A laminate having a wireless communication circuit embedded within the laminate, comprising:
a first paper layer;
a second paper layer disposed above the first paper layer;
an insulating layer disposed above the second paper layer;
an antenna provided as a set of windings on one of the first paper layer and the second paper layer;
a wireless communication circuit;
an electrically conducting connector segment disposed on the other of the first paper layer and the second paper layer, the electrically conducting connector segment being in electrical contact with the antenna and the wireless communication circuit to define a complete circuit; and
wherein the first paper layer and the insulating layer encapsulate the wireless communication circuit within the laminate.

2. The laminate having a wireless communication circuit embedded within the laminate according to claim 1, the antenna comprising a particulate, electrically-conductive material and a binder, the antenna optionally further comprising microcrystalline cellulose.

3. The laminate having a wireless communication circuit embedded within the laminate according to claim 2, wherein the particulate, electrically-conductive material comprises silver particles.

4. The laminate having a wireless communication circuit embedded within the laminate according to claim 1, the laminate further comprising first and second vias through the paper layer on which the antenna is provided, one of the first via and the second via being in electrical contact with a terminus of the antenna and the other of the first via and the second via being in electrical contact with the wireless communication circuit.

5. The laminate having a wireless communication circuit embedded within the laminate according to claim 1, the wireless communication circuit and the antenna both being disposed on either the first paper layer or the second paper layer.

6. The laminate having a wireless communication circuit embedded within the laminate according to claim 1, further comprising first and second vias through the first paper layer and/or the second paper layer to electrically connect the electrically conducting connector segment to both the wireless communication circuit and a terminus of the antenna.

7. The laminate having a wireless communication circuit embedded within the laminate according to claim 1, wherein the wireless communication circuit is configured to provide, to a reader device, a reference to an electronic resource to be retrieved by the reader device when the reader is within a certain distance of the wireless communication circuit.

8. The laminate having a wireless communication circuit embedded within the laminate according to claim 7, wherein the reference includes a Universal Resource Locator (URL).

9. The laminate having a wireless communication circuit embedded within the laminate according to claim 7, wherein the electronic resource is stored on a host operating on a local-area network (LAN) or a wide-area network (WAN).

10. (canceled)

11. (canceled)

12. The laminate having a wireless communication circuit embedded within the laminate according to claim 1, wherein one or more of the first paper layer and the second paper layer is impregnated with a resin material.

13. (canceled)

14. (canceled)

15. The laminate having a wireless communication circuit embedded within the laminate according to claim 1, the laminate further comprising a power source coupled to the wireless communication circuit, the power source also being embedded within the substrate.

16. The laminate having a wireless communication circuit embedded within the laminate according to claim 15, the power source comprising a battery.

17. The laminate having a wireless communication circuit embedded within the laminate according to claim 16, the thin film battery comprising an anode, a cathode, and an electrolyte between the anode and the cathode.

18. The laminate having a wireless communication circuit embedded within the laminate according to claim 17, the thin film battery further comprising an anode current collector in contact with the anode and a cathode current collector in contact with the cathode.

19. (canceled)

20. The laminate having a wireless communication circuit embedded within the laminate according to claim 17, wherein the electrolyte is present in a further paper layer disposed between the anode and the cathode, the further paper layer being impregnated with the electrolyte.

21. An article comprising the laminate having a wireless communication circuit embedded within the laminate according to claim 1 disposed on a supporting substrate.

22. A laminate having a wireless communication circuit embedded within the laminate, comprising:
a first paper layer;
a second paper layer disposed above the first paper layer;
an insulating layer disposed above the second paper layer;
an antenna comprising a particulate, electrically-conductive material and a binder, the antenna further optionally comprising microcrystalline cellulose, the antenna provided as a set of windings arranged on one of the first paper layer and the second paper layer;
a wireless communication circuit in electrical contact with the antenna in a complete circuit;
wherein the first paper layer and the insulating layer encapsulate the wireless communication circuit within the laminate.

23. (canceled)

24. The laminate having a wireless communication circuit embedded within the laminate according to claim 22, the laminate further comprising first and second vias through the paper layer on which the antenna is provided, one of the first via and the second via being in electrical contact with a terminus of the antenna and the other of the first via and the second via being in electrical contact with the wireless communication circuit.

25. The laminate having a wireless communication circuit embedded within the laminate according to claim 22, the wireless communication circuit and the antenna both being disposed on either the first paper layer or the second paper layer.

26. The laminate having a wireless communication circuit embedded within the laminate according to claim 22, further comprising an electrically conducting connector segment disposed on the other of the first paper layer and the second paper layer, and first and second vias through the first paper layer and/or the second paper layer to electrically connect the electrically conducting connector segment to both the wireless communication circuit and a terminus of the antenna.

27.-56. (canceled)

57. A laminate having a battery embedded within the laminate, comprising:
a first paper layer;
a second paper layer disposed above the first paper layer;
an insulating layer disposed above the second paper layer;
the battery comprising a thin film battery provided on one of the first paper layer and the second paper layer,
wherein the first paper layer and the insulating layer encapsulate the battery within the laminate.

58. The laminate having a battery embedded within the laminate according to claim 57, the thin film battery comprising an anode, a cathode, and an electrolyte between the anode and the cathode.

59. The laminate having a battery embedded within the laminate according to claim 58, the thin film battery further comprising an anode current collector in contact with the anode and a cathode current collector in contact with the cathode.

60. (canceled)

61. (canceled)
